(19) United States
(12) Patent Application Publication
(10) Pub. No.: US 2009/0262077 A1
(43) Pub. Date: Oct. 22, 2009

(54) KEYSWITCH AND KEYBOARD

(75) Inventors: Lei Lung Tsai, Taipei County (TW); Yun Nien Chai, Tainan City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Darfon Electronics Corp., Taoyuan (TW)

(21) Appl. No.: 12/423,377

(22) Filed: Apr. 14, 2009

(30) Foreign Application Priority Data
Apr. 18, 2008 (TW) 097206683

(51) Int. Cl. H03M 11/02; H01H 13/705; G08C 19/12; G06F 3/02

(52) U.S. Cl. 345/168; 200/344; 341/22; 341/176

(57) ABSTRACT

The invention discloses a keyswitch and a keyboard which makes use of the keyswitch. The keyswitch is co-operated with an antenna. The antenna is used for receiving a signal transmitted by an electronic product. The keyswitch includes a keycap, a conductive foil, and a communication module. The conductive foil forms at least one part of the antenna. The communication module is used for receiving the signal via the antenna.

### BACKGROUND OF THE INVENTION

1. Field of the Invention

The present invention relates generally to a keyswitch and a keyboard which makes use of the keyswitch, and more particularly, the present invention relates to a keyswitch and a keyboard disposing part of devices, which is originally disposed inside a computer, in peripheral apparatuses, so as to reduce the volume of the assembly allocation structure of the computer.

2. Description of the Prior Art

As the promotion of technology, electronic products have been becoming more and more popular. Electronic data processing has already been commonly in human's daily life. Especially the electronic-data has absolutely overthrown the conventional style of storing data. The style of the storing space, particularly, tends towards microminiaturization.

The style of the storing space (memory media) mentioned above has been changing substantially, from papers to microfilms, hard disks, any kinds of flexible disks, keychain drives, optical disks, etc, which has reduced the volume to thousands-fold. However, the microminiaturization of the equipments for processing the electronic-data obviously falls behind.

A personal computer for example, some support members are required inside the frame to support the case to provide sufficient space and structural strength. Each computer has a main board, and many devices and cables are inserted thereon so as to form a complicated main board. Plural hard and floppy disk units, fans and power supplies, etc, are disposed inside of each frame. For a common upright computer frame, it is formed upright because the main board is configured vertically under the optical disk so as to make the conventional computer frame ponderous and space-consuming. Moreover, the main board is a large flat which occupies a large space and makes the computer frame incapable of being narrowed.

It is thus evident that the reason why the computers on the market now are large in volume, is because the large volume of the heat dissipation devices, the use of power supplies, the use of floppy disk units, the large volume of the main boards, inappropriate allocation of components and the use kinds of cables, etc. Especially the inappropriate allocation of components and the use of kinds of cables consume a great portion of space. For example, the main board is connected to an optical disk, a hard disk, a CD-R machine, a power supply and a floppy disk, etc, by means of cables, which consume more spaces than the main board, the optical disk and the hard disk, and this is exactly the main reason why the computer could not be narrowed.

However, despite the development in the last decade that the general computer (e.g. the desktop computer) are made smaller by means of disposing elements with smaller standards inside the frame to reach the purpose of microminiaturization and avoiding space-consuming. Although the computer mentioned above are narrowed, however, the elements with smaller standards such as the optical disk, the hard disk and the power supply increase the cost of the main frame which results in the high price.

On the other hand, though the presence of the notebook computer to the public, the reduction of the entire volume is about ten-fold, which is a far cry from the development of the style of the storing space. If the volume of the computer could be decreased, it would not only meet every user's expectation but also lower the space-consumption in the work place. Therefore, how to improve the computer's function as well as to decrease the volume of a computer is the aim that we work for.

Thereby, the main aspect of the present invention is to provide a keyswitch and a keyboard which making use of the keyswitch. The keyswitch and the keyboard dispose part of devices, which is originally disposed inside of a main frame, in peripheral apparatuses, so as to provide an assembly proposal which is capable of reducing the assembly allocation structure of the computer to reach the purpose of the space inside the computer completely used and solve the problem mentioned above.

### SUMMARY OF THE INVENTION

An aspect of the invention is to provide a keyswitch. The keyswitch could be co-operated with an antenna. The antenna is used for receiving a signal transmitted by an electronic product. The keyswitch includes a keycap, a conductive foil, and a communication module. The keycap has a bottom surface. The conductive foil is fixed on the bottom surface in a specific way to form at least one part of the antenna. The communication module is electrically connected to the conductive foil for receiving the signal via the antenna.

Another aspect of the invention is to provide a keyswitch. The keyswitch could be co-operated with an antenna. The antenna is used for receiving a signal transmitted by an electronic product. The keyswitch includes a keycap, a conductive foil, and a communication module. The keycap has a first assembly part and a second assembly part. The conductive foil is clipped in the keycap by means of assembling the first assembly part and the second assembly part to form at least one part of the antenna. The communication module is electrically connected to the conductive foil for receiving the signal via the antenna.

Another aspect of the invention is to provide a keyswitch. The keyswitch could be co-operated with an antenna. The antenna is used for receiving a signal transmitted by an electronic product. The keyswitch includes a conductive rubber dome, a conductive ring, and a communication module. The conductive ring is slipping on the conductive rubber dome, wherein the conductive rubber dome and the conductive ring form at least one part of the antenna. The communication module is electrically connected to the conductive ring for receiving the signal via the antenna.

Another aspect of the invention is to provide a keyboard. The keyboard could be co-operated with an antenna. The antenna is used for receiving a signal transmitted by an electronic product. The keyboard includes a plurality of keyswitches, at least one conductive foil, and a communication module. Each of the keyswitches has a keycap, and each of the keycaps has a bottom surface. Each of the conductive foils is fixed on the bottom surface of the corresponding keycap in a specific way to form at least one part of the antenna. The communication module is electrically connected to at least one conductive foil for receiving the signal via the antenna.

Another aspect of the invention is to provide a keyboard. The keyboard could be co-operated with an antenna. The antenna is used for receiving a signal transmitted by an electronic product. The keyboard includes a plurality of keyswitches, at least one conductive foils and a communication module. Each of the keyswitches has a keycap, and at least one of the keycaps has a first assembly part and a second assembly part. Each of the conductive foils is corresponding to one of the keycaps, and each of the conductive foils is clipped and fixed in the corresponding keycap by assembling the corresponding first assembly part and the corresponding second assembly part to form at least one part of the antenna. The communication module is electrically connected to at least one conductive foil for receiving the signal via the antenna.

Another aspect of the invention is to provide a keyboard. The keyboard could be co-operated with an antenna. The antenna is used for receiving a signal transmitted by an electronic product. The keyboard includes a plurality of keyswitches, at least one conductive foil, and a communication module. Each of the keyswitches has a conductive rubber dome. Each of the conductive rings is slipping on a corresponding conductive rubber dome. Each of the conductive rings and the corresponding conductive rubber dome form at least one part of the antenna. The communication module is electrically connected to at least one conductive ring for receiving the signal via the antenna.

Accordingly, the keyswitch and the keyboard of the present invention are to dispose part of devices, which is originally disposed inside of a main frame, in peripheral apparatuses (the keyswitch and the keyboard), so as to reduce the assembly allocation structure of the computer. Thereby, the keyswitch and the keyboard of the invention could not only partake of the volume loading inside the computer but also diversely make use of the part devices in the peripheral apparatuses.

The objective of the present invention will no doubt become obvious to those of ordinary skill in the art after reading the following detailed description of the preferred embodiment, which is illustrated in the various figures and drawings.

### BRIEF DESCRIPTION OF THE APPENDED DRAWINGS

FIG. 1A is a functional block illustrating a keyswitch according to an embodiment of the invention.

FIG. 1B is an exploded view illustrating the keyswitch in FIG. 1A.

FIG. 2 illustrates one part of a keyswitch according to an embodiment of the invention.

FIG. 3A is a cross sectional view of a keycap of a keyswitch before assembly according to another embodiment of the invention.

FIG. 3B is a cross sectional view of a keycap of the keyswitch after assembly according to the embodiment of the invention.

FIG. 4 illustrates a keyswitch according to another embodiment of the invention.

FIG. 5 illustrates a keyboard according to an embodiment of the invention.

### DETAILED DESCRIPTION OF THE INVENTION

The present invention provides a keyswitch and a keyboard which makes use of the keyswitch, and more particularly, the present invention relates to a keyswitch and a keyboard disposing part of devices, which is originally disposed inside a computer, in peripheral apparatuses, so as to reduce the assembly allocation structure of the main frame. The details of the embodiment will be described as the followings to explain the essence and the advantages of the present invention.

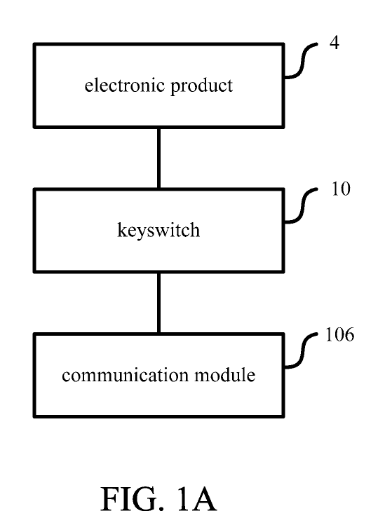

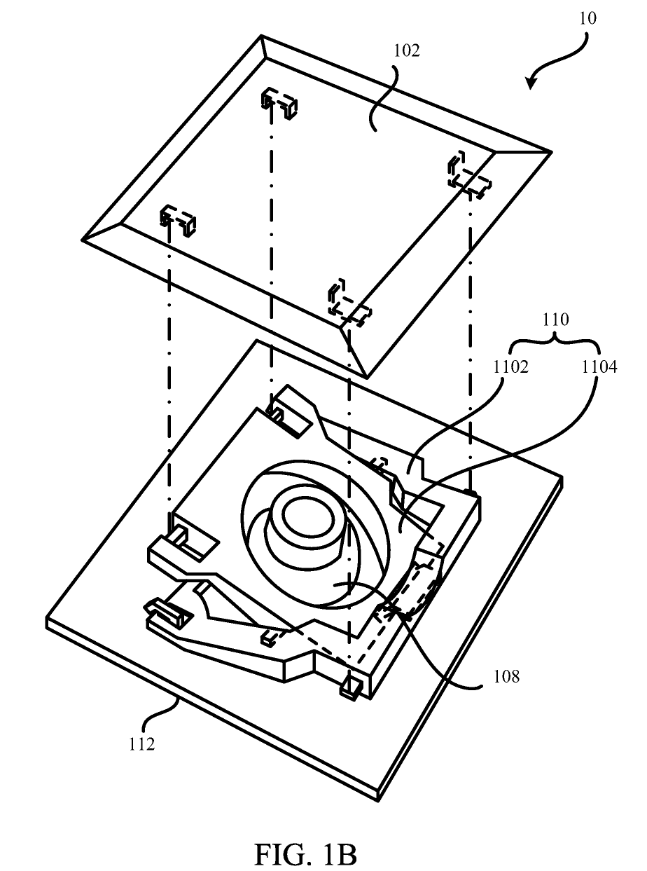

Please refer to FIG. 1A, FIG. 1B and FIG. 2. FIG. 1A is a functional block illustrating a keyswitch according to an embodiment of the invention. FIG. 1B is an explored view illustrating the keyswitch in FIG. 1A. FIG. 2 illustrates one part of a keyswitch 10 according to the embodiment of the invention. As illustrated in FIG. 1A, according to an embodiment, the keyswitch 10 could be a basic structure of the invention. The relationship between the keyswitch 10 and the electronic product 4 and that between the keyswitch 10 and a communication module 106 could be wired or wireless. The keyswitch 10 could be co-operated with an antenna. The antenna could be used for receiving a signal transmitted by the electronic product 4. The keyswitch 10 includes a keycap 102, a conductive foil 104, the communication module 106, a rubber dome 108, a scissor-structure supportive member 110 and a base plate 112. The details of the embodiment, including the structure of each devices and the relationship between each other, of the keyswitch 10 will be described as the followings.

As illustrated in FIG. 1B, the scissor-structure supportive member 110 with the first arm member 1102 and the second member 1104 is pivoted on the base plate 112. The keycap 102 of the keyswitch 10 are assembled by means of pivoting the scissor-structure supportive member 110 on the keycap 102 so that the scissor-structure supportive member 110 could support the keyswitch 10 while the keyswitch 10 is vertically pressed.

As illustrated in FIG. 2, the keycap 102 has a bottom surface 1022. The conductive foil 104 is fixed on the bottom surface 1022 of the keycap 102 in a specific way to form at least one part of the antenna. The communication module 106 is electrically connected to the conductive foil 104 for receiving the signal via the antenna.

In an embodiment, the specific way mentioned above could be sticking the conductive foil 104 on the bottom surface 1022 of the keycap 102 by means of a colloid. More particularly, the colloid in the embodiment could be, but not limited to, a slow-drying silica gel. The colloid, that is to say, could be any kind of material which helps drying to reach the purpose of sticking the conductive foil 104 on the bottom surface 1022 of the keycap 102.

In another embodiment, the specific way mentioned above could be to fix the conductive foil 104 on the bottom surface 1022 of the keycap 102 by means of an in-mold roller process. Otherwise, the specific way mentioned above could be to form the conductive foil 104 on the bottom surface 1022 of the keycap 102 by means of an electroplating process. The specific way may not be limited the processes mentioned above, but any kinds of processes which could reach the purpose of sticking the conductive foil 104 on the bottom surface 1022 of the keycap 102.

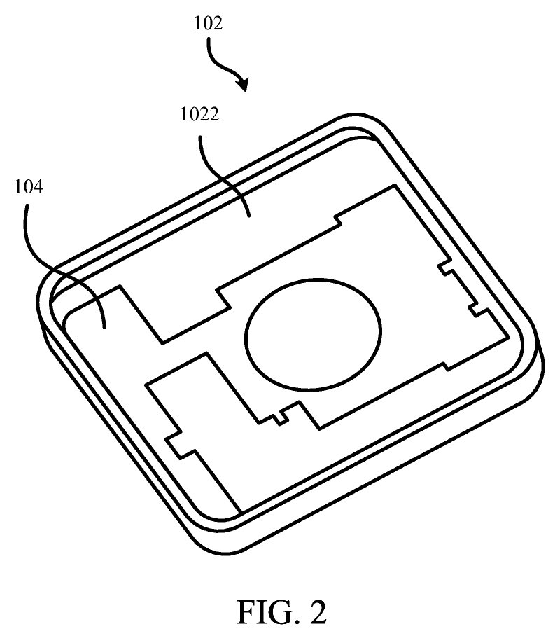

Please refer to FIG. 3A and FIG. 3B. FIG. 3A is a cross sectional view of a keycap 202 of a keyswitch 10 before assembly according to another embodiment of the invention. FIG. 3B is a cross sectional view of a keycap 202 of the keyswitch 10 after assembly according to this embodiment of the invention. The details of the keyswitch 10 of the embodiment, including the structure of each devices and the relationship between each other, will be described as the followings.

As illustrated in FIG. 3A, similarly, the keyswitch could be co-operated with an antenna. The antenna could be used for receiving a signal transmitted by an electronic product 4. The keyswitch 10 includes a keycap 202, a conductive foil 104, and a communication module 106. Particularly, the keycap 202 has a first assembly part 2022 and a second assembly part 2024.

As illustrated in FIG. 3B, the conductive foil 104 is clipped in the keycap 202 by means of assembling the first assembly part 2022 and the second assembly part 2024 of the keycap 202 to form at least one part of the antenna. The communication module 106 is electrically connected to the conductive foil 104 for receiving the signal via the antenna. Therefore, the two-piece keycap structure 202 according to the embodiment could reach the purpose of clipping the conductive foil 104 in the keycap 202 without any extra cost.

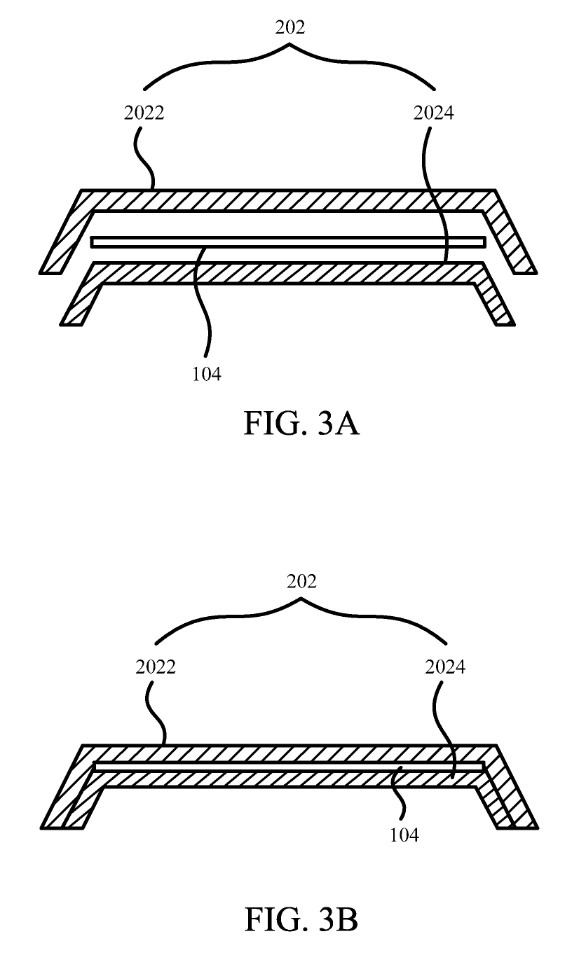

Please refer to FIG. 4. FIG. 4 illustrates a keyswitch 10 according to another embodiment of the invention. The keyswitch 10 could be co-operated with an antenna. The antenna is used for receiving a signal transmitted by an electronic product 4. The keyswitch 10 includes a conductive rubber dome 308, a conductive ring 3082, and a communication module 106. The details of the keyswitch 10 of the embodiment, including the structure of each devices and the relationship between each other, will be described as the followings.

As illustrated in FIG. 4, the conductive ring 3082 could be slipping on the conductive rubber dome 308. The conductive rubber dome 308 and the conductive ring 3082 form at least one part of the antenna. The communication module 106 is electrically connected to the conductive ring 3082 for receiving the signal via the antenna.

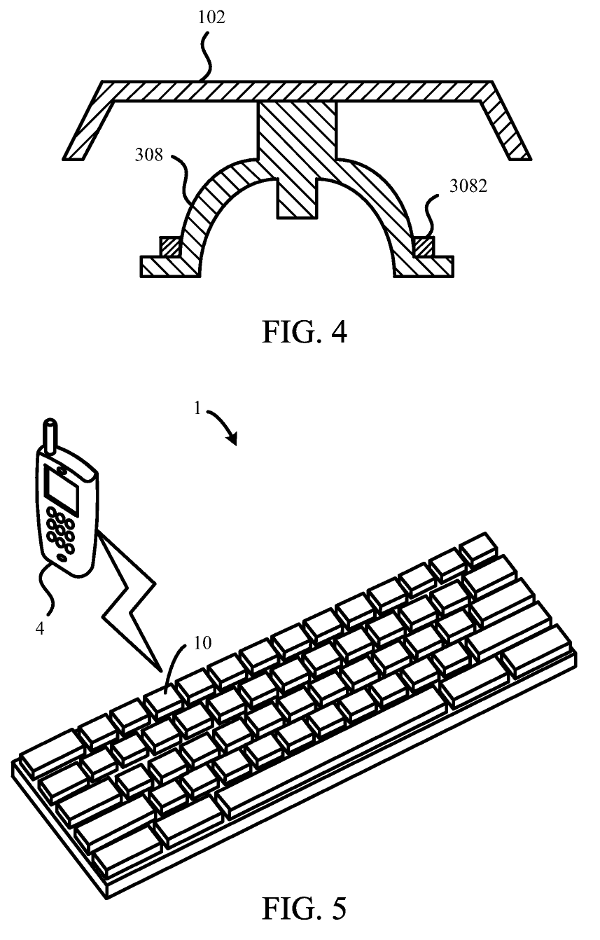

Please refer to FIG. 5. FIG. 5 illustrates a keyboard 1 according to an embodiment of the invention. The keyboard 1 could be co-operated with an antenna. The antenna is used for receiving a signal transmitted by an electronic product 4 (a mobile phone is taken as an example in FIG. 5). The basic structure of the keyswitch 10 of the keyboard 1 is shown in FIG. 2, and the details are not described again here. The keyboard 1 includes a plurality of keyswitches 10, at least one conductive foil 104, and a communication module 106. Each of the keyswitches 10 has a keycap 102, and each of the keycaps 102 has a bottom surface 1022.

Particularly, in an embodiment, each of the conductive foils 104 is fixed on the corresponding bottom surface 1022 of one of the keycaps 102 in the specific way mentioned above to form at least one part of the antenna. The communication module 106 is electrically connected to at least one conductive foil 104 for receiving the signal via the antenna. Therefore, the number of antennas disposed on the keyswitches 10 of the keyboard 1 could depend on the required intensity of receiving signals or other special conditions. For example, if a strong intensity of receiving signals is required, then the conductive foils 104 could be disposed in each keyswitches 10 of the keyboard 1. Or if the keyboard has a special requirement of common intensity of receiving signals and claims for a longer life time of the keyswitch 10 with the conductive foils 104, the conductive foils 104 could be selectively disposed on a keyswitch 10 which is rarely pressed by users.

According to another embodiment of the invention, the basic structure of the keyswitch 10 of the keyboard 1 is shown in FIG. 3A and FIG. 3B, and the details are not described again here. Particularly, each of the keyswitches 10 has a keycap 202, and at least one of the keycaps 202 has a first assembly part 2022 and a second assembly part 2024. Each of the conductive foils 104 is corresponding to one of the keycaps 202, and each of the conductive foils 104 is clipped in the corresponding keycap 202 by assembling the corresponding first assembly part 2022 and the corresponding second assembly part 2024 to form at least one part of the antenna. The communication module 106 is electrically connected to at least one conductive foil 104 for receiving the signal via the antenna. Therefore, the number of antennas disposed on the keyswitches 10 of the keyboard 1 could depend on the required intensity of receiving signals or other special conditions.

According to another embodiment, the basic structure of the keyswitches 10 of the keyboard 1 is shown in FIG. 4, and the details are not described again here. More particularly, each of the keyswitches 10 has a conductive rubber dome 308. Each of the conductive rings 3082 is slipping on a corresponding conductive rubber dome 308. Each of the conductive rings 3082 and the corresponding conductive rubber dome 308 form at least one part of the antenna. The communication module 106 is electrically connected to the conductive ring 3082 for receiving the signal via the antenna. Therefore, the number of antennas disposed on the keyswitches 10 of the keyboard 1 could depend on the required intensity of receiving signals or other special conditions.

In another embodiment, the communication module 106 could be, but not limited to, a bluetooth communication module, a radio frequency module, etc. Thus, if the bluetooth communication module 106 mentioned will be adopted, the electronic product 4 should be an electronic product using a bluetooth technique. Similarly, if the radio frequency communication module mentioned will be adopted, the electronic product 4 should be an electronic product using a radio frequency technique.

From the detailed descriptions of the embodiments of the invention mentioned above, it is clear that the keyswitch and the keyboard dispose part of devices, which is originally disposed inside the computer, in peripheral apparatuses, so as to provide an assembly proposal which is capable of reducing the assembly allocation structure of the computer to reach the purpose of the space inside the computer completely used. Thereby, the keyswitch and the keyboard of the invention could not only partake of the volume loading inside the computer but also diversely make use of the part devices in the peripheral apparatuses. Moreover, the number of antennas disposed on the keyswitches of the keyboard could depend on the required intensity of receiving signals or other special conditions.

Although the present invention has been illustrated and described with reference to the preferred embodiment thereof, it should be understood that it is in no way limited to the details of such embodiment but is capable of numerous modifications within the scope of the appended claims.

What is claimed is:

1. A keyswitch co-operated with an antenna, the antenna being used for receiving a signal transmitted by an electronic product, the keyswitch comprising:
a keycap, having a bottom surface;
a conductive foil fixed on the bottom surface in a specific way to form at least one part of the antenna; and
a communication module electrically connected to the conductive foil, for receiving the signal via the antenna.

2. The keyswitch of claim 1, wherein the specific way is to stick the conductive foil on the bottom surface by means of a colloid.

3. The keyswitch of claim 2, wherein the colloid is a slow-drying silica gel.

4. The keyswitch of claim 1, wherein the specific way is to fix the conductive foil on the bottom surface by means of an in-mold roller process.

5. The keyswitch of claim 1, wherein the specific way is to form the conductive foil on the bottom surface by means of an electroplating process.

6. The keyswitch of claim 1, wherein the communication module is a bluetooth communication module.

7. The keyswitch of claim 6, wherein the electronic product is an electronic product using a bluetooth technique.

8. A keyswitch co-operated with an antenna, the antenna being used for receiving a signal transmitted by an electronic product, the keyswitch comprising:
a keycap, having a first assembly part and a second assembly part;
a conductive foil clipped in the keycap by means of assembling the first assembly part and the second assembly part to form at least one part of the antenna; and
a communication module electrically connected to the conductive foil, for receiving the signal via the antenna.

9. The keyswitch of claim 8, wherein the communication module is a bluetooth communication module.

10. The keyswitch of claim 9, wherein the electronic product is an electronic product using a bluetooth technique.

11. A keyswitch co-operated with an antenna, the antenna being used for receiving a signal transmitted by an electronic product, the keyswitch comprising:
a conductive rubber dome;
a conductive ring slipping on the conductive rubber dome, wherein the conductive rubber dome and the conductive ring form at least one part of the antenna; and
a communication module electrically connected to the conductive ring, for receiving the signal via the antenna.

12. The keyswitch of claim 11, wherein the communication module is a bluetooth communication module.

13. The keyswitch of claim 12, wherein the electronic product is an electronic product using a bluetooth technique.

14. A keyboard co-operated with an antenna, the antenna being used for receiving a signal transmitted by an electronic product, the keyboard comprising:
a plurality of keyswitches, each of the keyswitches having a keycap, and each of the keycaps having a bottom surface;
at least one conductive foils, each of the conductive foils being fixed on the corresponding bottom surface of one of the keycaps in a specific way to form at least one part of the antenna; and
a communication module electrically connected to the conductive foils, for receiving the signal via the antenna.

15. The keyboard of claim 14, wherein the specific way is to stick the conductive foil on the bottom surface by means of a colloid.

16. The keyboard of claim 15, wherein the colloid is a slow-drying silica gel.

17. The keyboard of claim 14, wherein the specific way is to fix the conductive foil on the corresponding bottom surface by means of an in-mold roller process.

18. The keyboard of claim 14, wherein the specific way is to form the conductive foil on the corresponding bottom surface by means of an electroplating process.

19. The keyboard of claim 14, wherein the communication module is a bluetooth communication module.

20. The keyboard of claim 19, wherein the electronic product is an electronic product using a bluetooth technique.

21. A keyboard co-operated with an antenna, the antenna being used for receiving a signal transmitted by an electronic product, the keyboard comprising:
a plurality of keyswitches, each of the keyswitches having a keycap, and at least one keycap having a first assembly part and a second assembly part;
at least one conductive foils, each of the conductive foils corresponding to one of the keycaps, each of the conductive foils being clipped in the corresponding keycap by assembling the corresponding first assembly part and the corresponding second assembly part to form at least one part of the antenna; and
a communication module electrically connected to the conductive foils, for receiving the signal via the antenna.

22. The keyboard of claim 21, wherein the communication module is a bluetooth communication module.

23. The keyboard of claim 22, wherein the electronic product is an electronic product using a bluetooth technique.

24. A keyboard co-operated with an antenna, the antenna being used for receiving a signal transmitted by an electronic product, the keyswitch comprising:
a plurality of keyswitches, and each of the keyswitches having a conductive rubber dome;
at least one conductive rings, each of the conductive rings slipping on one corresponding conductive rubber dome of the conductive rubber domes, wherein each of the conductive rings and the corresponding conductive rubber dome form at least one part of the antenna; and
a communication module electrically connected to each of the conductive rings, for receiving the signal via the antenna.

25. The keyboard of claim 24, wherein the communication module is a bluetooth communication module.

26. The keyboard of claim 25, wherein the electronic product is an electronic product using a bluetooth technique.
